(19) United States
(12) Patent Application Publication
(10) Pub. No.: US 2025/0372300 A1
(43) Pub. Date: Dec. 4, 2025

(54) Perpendicular MR SAF

(71) Applicant: Allegro MicroSystems, LLC, Manchester, NH (US)

(72) Inventor: Clarisse Ducruet, Chambéry (FR)

(73) Assignee: Allegro MicroSystems, LLC, Manchester, NH (US)

(21) Appl. No.: 18/679,972

(22) Filed: May 31, 2024

(51) Int. Cl. H01F 41/32; C23C 14/06; C23C 14/14; C23C 14/34; G01R 33/09; H01F 10/32

(52) U.S. Cl. CPC H01F 41/32; C23C 14/067; C23C 14/14; C23C 14/34; G01R 33/098; H01F 10/3254; H01F 10/3272; H01F 10/3286

(57) ABSTRACT

Method for forming a magnetoresistive element by forming a sense layer having a free sense magnetization, a reference layer having a fixed reference magnetization, wherein the reference layer is formed by deposition in a Krypton atmosphere, a tunnel barrier layer between the reference layer and the sense layer, and a hard layer having a fixed reference magnetization layer opposite to that of the reference layer. The magnetoresistive element may be configured to measure an external magnetic field oriented substantially perpendicular to the plane of the reference layer. The reference magnetizations of the reference and hard layers may be oriented substantially perpendicularly to the plane of the reference and hard layers. The sense magnetization may have a vortex configuration in the absence of an external magnetic field.

### BACKGROUND

As is known in the art, magnetic field sensors are used in a variety of applications. Some sensors provide two-dimensional (2D) magnetic field sensing in an X-Y plane, such as by using orthogonal sensors. Some known sensors can sense magnetic fields in a Z-axis direction, such as by using separate single-axis planar magnetoresistive sensors installed perpendicularly to a two-axis planar sensor. Other Z-axis sensor include a flux guide to convert a magnetic field from the Z-axis direction into magnetic field components in the X- and Y-axis directions.

### SUMMARY

Example embodiments of the disclosure provide methods and apparatus for MR sensors having z-axis sensing with enhanced performance provided by Krypton atmosphere deposition of certain stack layers. In embodiments, layers in the reference layer and/or hard layer are deposited in a Krypton atmosphere, which improves the perpendicular magnetic anisotropy (PMA) and the RKKY coupling strength of the perpendicular synthetic antiferromagnetic (pSAF) so as to increase the field stability range. By stiffening the pSAF structure, the maximum of the stability fields is increased which improves the usable range of example z-axis magnetic sensors as compared to conventional sensors.

In one aspect, a method comprises: forming a series of layers for a magnetoresistive element, including: forming a sense layer having a free sense magnetization; forming a tunnel barrier layer between the sense layer and a reference layer; forming the reference layer having a fixed reference magnetization, wherein the reference layer is formed by deposition in an atmosphere with a noble gas having an atomic weight greater than Argon; forming a hard layer having a fixed reference magnetization layer opposite to that of the reference layer due to a metallic layer in between the hard layer and the reference layer, wherein the magnetoresistive element is configured to measure an external magnetic field oriented substantially perpendicular to the plane of the reference layer; wherein the reference magnetizations of the reference and hard layers are oriented substantially perpendicularly to the plane of the reference and hard layers; and wherein the sense magnetization comprises a vortex configuration in the absence of an external magnetic field, the vortex configuration being substantially parallel to the plane of the sense layer and having a vortex core magnetization along an out-of-plane axis substantially perpendicular to the plane of the sense layer.

A method can further include one or more of the following features: the reference layer is formed by deposition in the atmosphere with a noble gas having an atomic weight greater than Argon, the reference layer comprises alternating layers of Pt and Co, Pt layers in the alternating layers of Pt and Co range from 0.2 nm to 2.0 nm in thickness, Co layers in the alternating layers of Pt and Co range from 0.2 nm to 2.0 nm in thickness, the reference layer comprises Pd, the reference layer includes a FeCoB layer, the FeCoB layer comprises Fe_{y}Co_{80-y} B₂₀ where y is between 5 and 75, a thickness of the FeCoB layer ranges from 0.2 nm to 2.0 nm in thickness, the FeCoB layer is formed by deposition in the atmosphere, the reference layer includes a Ta layer deposited in the Kr atmosphere, the Ta layer has a thickness between 0.1 nm and 0.5 nm, the reference layer includes a Tungsten layer deposited in a the atmosphere with a noble gas having an atomic weight greater than Argon, the Tungsten layer has a thickness between 0.1 nm and 0.5 nm, the hard layer includes alternating layers of Pt and Co, the Pt layers and the Co layers in the alternating layers have thicknesses between 0.2 nm and 2.0 nm, the hard layer is deposited on a Pt buffer layer, the Pt buffer layer has a thickness from 0.2 nm to 50 nm, the hard layer is deposited on a Pd buffer layer, the hard layer includes alternating layers of Pd and Co, selecting thicknesses of alternating layers of Pt and Co in the reference layer and the hard layer for perpendicular anisotropy in the atmosphere with a noble gas having an atomic weight greater than Argon, selecting thicknesses of alternating layers of Pt and Co in the reference and hard layers for an AF plateau value, selecting thicknesses of alternating layers of Pt and Co in the reference and hard layers for given magnetic compensation characteristics, the metallic layer comprises Ru configured to establish RKKY AF coupling to obtain a perp SAF, selecting thicknesses of alternating layers of Pt and Co in the reference and hard layers for a given RKKY coupling strength, the magnetoresistive element forms a part of a z-axis MR sensor having field stability up to 250 mT, the noble gas having an atomic weight greater than Argon is Kr, and/or the noble gas having an atomic weight greater than Argon is Xe.

In another aspect, a magnetic field sensor is formed in accordance with one or more method features recited above.

In a further aspect, a method comprises: forming a series of layers for a magnetoresistive element, including: forming a sense layer having a free sense magnetization; forming a tunnel barrier layer between the sense layer and a reference layer; forming the reference layer having a fixed reference magnetization, wherein the reference layer is formed by deposition in an atmosphere with Krypton gas; forming a hard layer having a fixed reference magnetization layer opposite to that of the reference layer due to a metallic layer in between the hard layer and the reference layer, wherein the magnetoresistive element is configured to measure an external magnetic field oriented substantially perpendicular to the plane of the reference layer; wherein the reference magnetizations of the reference and hard layers are oriented substantially perpendicularly to the plane of the reference and hard layers; and wherein the sense magnetization comprises a vortex configuration in the absence of an external magnetic field, the vortex configuration being substantially parallel to the plane of the sense layer and having a vortex core magnetization along an out-of-plane axis substantially perpendicular to the plane of the sense layer.

### BRIEF DESCRIPTION OF THE DRAWINGS

The foregoing features of the disclosure, as well as the disclosure itself may be more fully understood from the following detailed description of the drawings, in which:

FIG. 1 shows an example MR layer structure and FIG. 1A shows an example implementation for a sensor having z-axis sensing with Krypton atmosphere material deposition to increase sensing characteristics as compared with known sensors;

FIG. 2A shows a switching mode for PMA>RKKY coupling strength and FIG. 2B shows a switching mode for PMA<RKKY coupling strength with hysteresis loops made in an out-of-plane (OOP) applied magnetic field (normalized M (H) loops are shown which are the magnetization divided by the saturation magnetization);

FIG. 3A and FIG. 3B show the response of an MR element having a Ta/Pt/[Co/Pt]xn stacks (one with various Co elementary thicknesses for a fixed Pt thickness, the opposite case for the other)—for each case, it is shown that Pt deposition in a Kr atmosphere significantly promotes PMA in the MR element and that the PMA behavior that demonstrates the enhanced Hc characteristics are provided by Kr atmosphere Pt deposition;

FIG. 4A shows for the hard layer of the perpendicular SAF and FIG. 4B shows for the reference layer of the perpendicular SAF that Kr gas deposition of Pt in the pSAF promotes PMA as seen by increase in Hc1 and Hc2 values as compared with deposition of Pt in an Ar atmosphere;

FIG. 5A shows the RKKY coupling field (Hcpl) as a function of elementary Co thickness and FIG. 5B shows AFmin (the minimum field stability range i.e. the usable range) where Kr deposition of Pt in the pSAF promotes RKKY coupling as seen by the increase in Hcpl and AFmin values; and

FIG. 6 is a flow diagram showing an example sequence of steps for forming an MR element in a Kr atmosphere.

### DETAILED DESCRIPTION

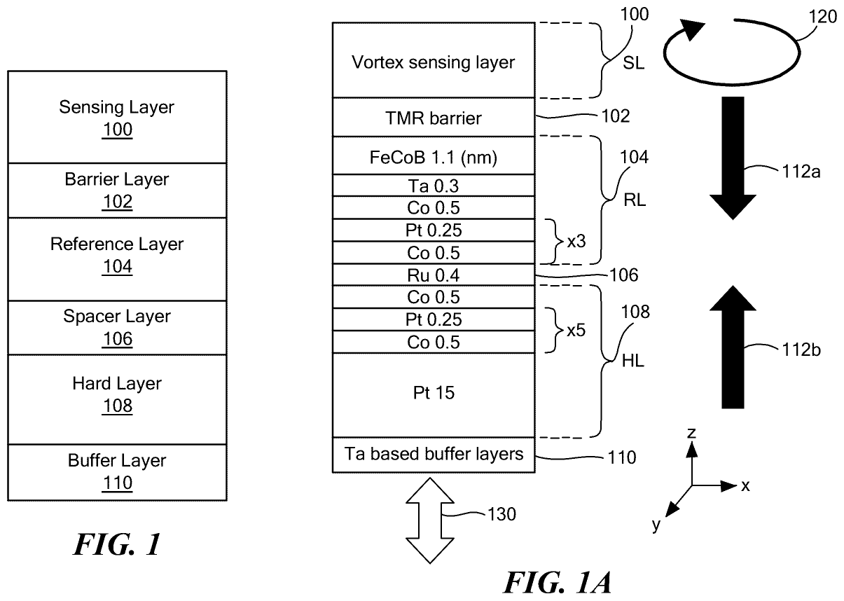

FIG. 1 shows an example MR layer structure and FIG. 1A shows an example implementation for a sensor having z-axis sensing with Krypton atmosphere material deposition to increase sensing characteristics as compared with known sensors. A vortex sensing layer 100 is separated from a reference layer 104 by a TMR barrier layer 102. A spacer layer 106 is located between the reference layer 104 and a hard layer 108. A buffer layer 110 can be adjacent to the hard layer 108. As indicated by the arrows 112a,b, in FIG. 1A, the reference and hard layers 104,108 have opposite pinning orientations.

In the illustrative embodiment of FIG. 1A, the hard layer 108 has alternating layers of Pt and Co with one of the Co layers abutting the Ru spacer layer 106. The reference layer 104 includes alternating layers of Pt and Co, as well as a layer of Ta and FeCoB, which abuts the barrier layer 102.

It understood that example dimensions and example numbers of layer repetitions are included in the figures to facilitate an understanding of illustrative embodiments of the disclosure and are not intended to limit the scope of the invention as claimed in any way.

Example embodiments of the disclosure provide MR sensors having enhanced z-axis sensing provided by Krypton atmosphere deposition of certain layers, such as the reference layer and/or hard layers 104, 108. Kr atmosphere deposition improves the perpendicular magnetic anisotropy and the RKKY coupling strength of the perpendicular synthetic antiferromagnetic (pSAF) so as to increase the field stability range. By this stiffening of the SAF structure, the maximum of the stability fields is increased which improves the usable range of example z-axis magnetic sensors as compared to conventional sensors. U.S. Patent Publication No. 2024/0027551, which is incorporated by reference, shows an example known z-axis sensor.

The sense magnetization 120 comprises a vortex configuration substantially parallel to the plane of the sense layer 100 in the absence of an external magnetic field. The reference layer 104 and the hard layer 108 have perpendicular magnetic anisotropy (PMA), such that the reference magnetization 112a, 112b is oriented substantially perpendicularly to the plane of the reference layer 104. The PMA characteristics of the reference and hard layer 104, 108 are described more fully below.

The sensor can measure an external magnetic field 130 oriented substantially perpendicularly to the plane of the sense and reference and layers 100, 104. The sense layer 100 has a sense magnetization direction distribution 120 with a vortex configuration in which the vortex magnetization curls in a circular path along the edge of the sense layer 100 and around a core of the vortex. The vortex magnetization direction may be arranged in a clockwise direction and may also be arranged in a counterclockwise direction.

During normal sensor operation, the magnetization of the vortex core can vary in accordance with the external magnetic field 130 in a direction substantially perpendicular to the plane of the sense layer 100, i.e., direction ±z. The magnetization of the vortex can be oriented in a +z direction or a −z direction. The size of the vortex core increases or decreases in the direction +z or −z when the magnitude of the external magnetic field 130 increases or decreases, respectively. However, during normal sensor operation the vortex core magnetization direction ±z is fixed.

As described above, a perpendicular SAF (pSAF) sets the out-of-plane (OOP) direction of the z-axis sensor. The pSAF, which includes the hard magnetic layer HL 108 and the reference layer RL 104, is based on [Co/Pt]ₓₙ multilayers deposited in the ultrathin to thin thickness range (i.e., 0.2 to 2.0 nm) exhibiting perpendicular magnetic anisotropy (PMA). The Ru spacer 106 sets the antiferromagnetic (AF) coupling between HL and RL layers 108, 104. Its thickness can be varied from 0.2 to 3.0 nm in example embodiments.

In example embodiments, the antiferromagnetic plateau should be stable up to more than 2500 Oe. In one particular embodiment, Co and Pt layer thicknesses and repetition number (n) are adjusted together with the RKKY strength. In embodiments, the materials of the reference and/or hard layer 104, 108 are deposited in a Kr-based sputtering deposition process.

In an example embodiment, a z-axis MR sensor has stability to fields up to 250 mT (2500 Oe), sensitivity around 0.8 mV/V/mT, linear operation in two regions: ±30 mT (300 Oe) and ±20 mT (200 Oe) around a ±110 mT bias field (1100 Oe), and −40° C. to +85° C. operation temperature.

It was found that using Kr gas for deposition of Pt materials in the reference and hard layers unexpectedly promoted PMA and RKKY coupling strength. This provides significant benefit in terms of rigidity of the SAF since there is an increase of the maximum stability field with Kr based materials. Thermal stability of the SAF is also improved.

In some embodiments, Kr deposition is used in the whole [Co/Pt]xn multilayer, including the thick Pt buffer (from 0.1 to 50 nm) and the MgO underlayer (assuming the layer 102 is a MgO barrier layer). Layers can include Ta, W, Mo, FeCoB, CoFeB, and their alloys.

It is understood that deposition of materials in MR elements using Argon is well known in the art. In general, since there is no expected structural or performance difference between using any of the noble gases, Argon is typically used since it is generally the least costly due to its natural abundance. In addition, the process, e.g., temperature, time, concentration, etc., for material deposition is well known. It was unexpected that using Kr instead of Ar would result in the desirable performance characteristics in MR elements with Pt in multilayers, which are discussed above.

In other embodiments, Xe deposition may be used in the whole [Co/Pt]xn multilayer to provide unexpected behavior characteristics similar to that of Kr deposition.

The atomic mass of Ar (40 g/mol) is less than that of Kr (84 g/mol) which is less than that of Xe (131 g/mol). The heavier atomic masses result in microstructural differences related to the energetics of the deposition process. The sputtering gas affects [Co/Pt]xn multilayers magnetic properties, e.g., (roughness=>interfacial mechanism, ultrathin Pt layers=>defects, different effective magnetic volume).

PMA increases by more than 25% with Pt (Kr) as compared to Ar atmosphere deposition. RKKY coupling strength is also promoted by Kr deposited Pt layers (25 to 30% higher), due to, for example, less energetic species plus different proportion of neutrals, influence on interface roughness, improved texture (growth), interdiffusion, more or less narrow grain boundaries that influence texture, and dependence versus annealing T.

Magnetron sputtering is performed with an inert gas. While small differences are expected from different inert gases, such as sputtering power (deposition rates), thin films roughness going from Argon to Krypton, the range of these differences from Argon to Krypton was very unexpected.

In Co/Pt multilayers systems, PMA comes from pure interfacial mechanisms, (typically with Co 0.6/Pt 1.8 nm elementary thicknesses, then quite thick). Strong OOP anisotropy can be further enhanced by the direct ferromagnetic and RKKY exchange couplings between the Co layers across the Pt interlayer which elementary thickness is then down to 0.2 to 0.5 nm (ultrathin range), in example embodiments. In some embodiments Pd can be used instead of Pt.

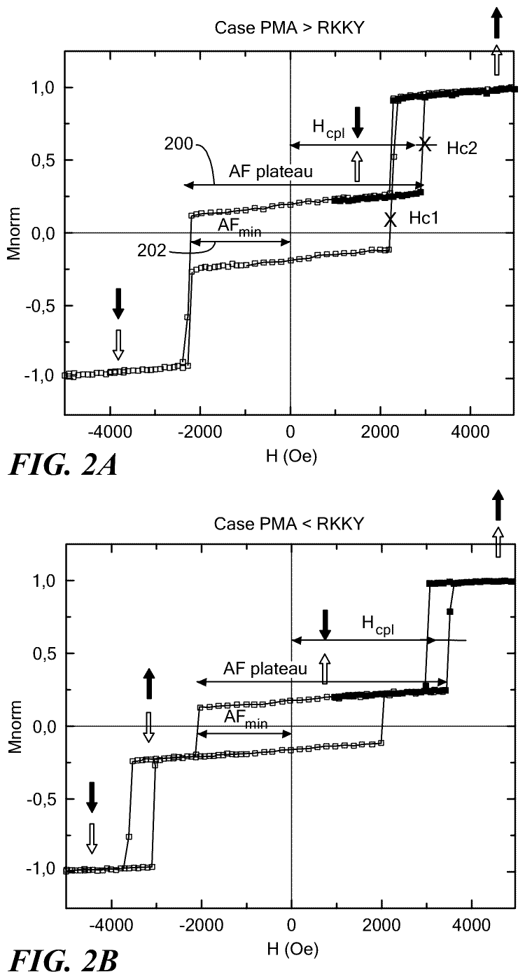

FIG. 2A shows a switching mode for PMA>RKKY coupling strength and FIG. 2B shows a switching mode for PMA<RKKY coupling strength with hysteresis loops made in an out-of-plane (OOP) applied magnetic field (normalized M (H) loops are shown which are the magnetization divided by the saturation magnetization). Due to the balance between PMA and RKKY coupling, two different switching modes can be reached; a PMA dominated reversal (RKKY energy smaller than Zeeman and anisotropy contributions); and the opposite situation (RKKY energy larger than anisotropy and Zeeman energies). Behavior is shown for the whole pSAF (reference layer and hard layer of an MR element), such as that shown in FIG. 1A.

Element behavior is shown for an AF plateau 200, which can be taken as the total width of stability, and an AFmin value 202, which represents the minimum field stability value (the usable range). It should be noted that the AF plateau 200 is not centered on zero. The switching modes can also be defined by Hc1 and Hc2 values that define the step size of the switching and by H_{cpl}, which defines the field value at which switch occurs.

Hc1 can be referred to as Hc,HL. It is the coercitive field of the hard layer of the pSAF.

Hc2 can be referred to as Hc,RL. It is the coercitive field of the reference layer of the pSAF.

For a given system, the stronger these values are, the stronger the perpendicular magnetic anisotropy is.

Hcpl represents the interlayer exchange coupling field (the RKKY coupling field basically).

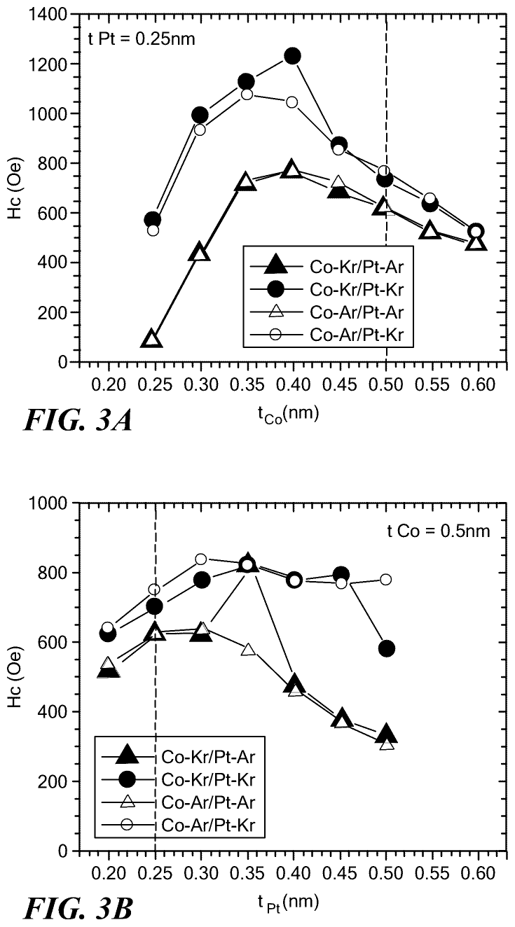

FIG. 3A shows the response of an MR element having a Ta/Pt/[Co/Pt]xn stack as a function of the Co thickness and FIG. 3B the response of an MR element having a Ta/Pt/[Co/Pt]xn stack as a function of the Pt thickness. In both cases, Pt deposition in a Kr atmosphere significantly promotes PMA in the MR element. FIGS. 3A and 3B show PMA behavior that demonstrates the enhanced Hc characteristics provided by Kr atmosphere Pt deposition. Four plots are shown where Co means Cobalt, Pt means Platinum, Kr refers to Krypton atmosphere deposition, and Ar is conventional Argon atmosphere deposition. As can be seen in the upper two curves (Co—Kr/Pt—Kr and Co—Ar/Pt—Kr), Pt deposition in a Kr atmosphere significantly promotes PMA in the MR element as compared to conventional Ar deposition. Co deposition in a Kr atmosphere provides a marginal benefit on PMA property

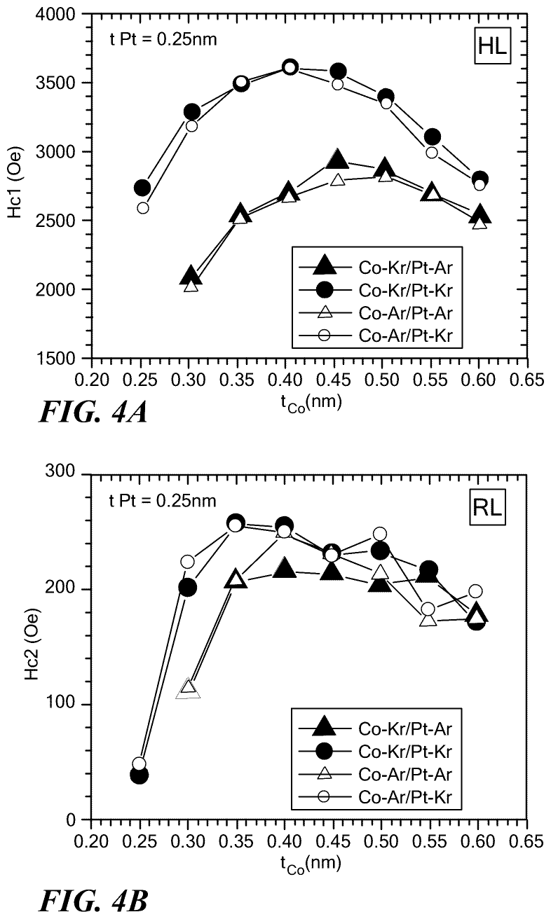

FIG. 4A shows for the hard layer and FIG. 4B shows for the reference layer that Kr gas deposition of Pt in the pSAF promotes PMA as seen by increase in Hc1 and Hc2 values as compared with deposition of Pt in an Ar atmosphere;

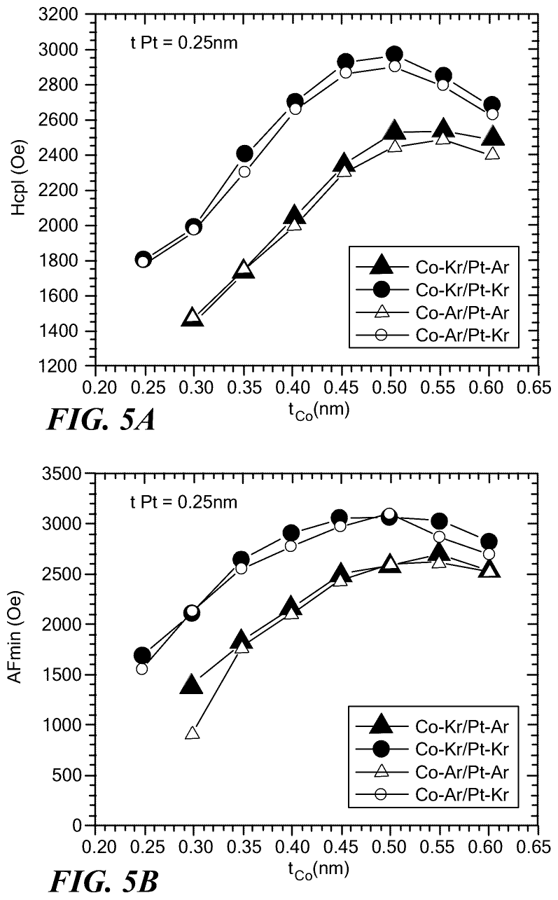

FIG. 5A shows the RKKY coupling field (Hcpl) as a function of elementary Co thickness and FIG. 5B shows AFmin (the minimum field stability range i.e. the usable range). Kr gas deposition of Pt in the pSAF promotes RKKY coupling as seen by increase in Hcp1 and AFmin values. These plots are for a Pt thickness of 0.25 nm and varying Co layer thicknesses shown on the x axis.

It is understood that lower thicknesses of the Pt and/or Co layers are contemplated to meet the needs of a particular application.

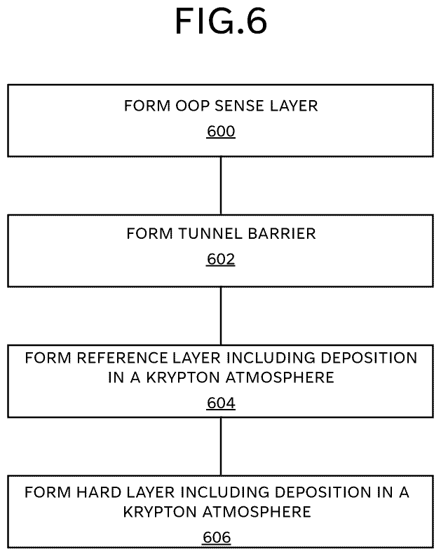

FIG. 6 shows an example sequence of steps for providing an MR element in a Kr atmosphere. In step 600, an out of plane sensing layer is formed. In step 602, a tunnel barrier layer is formed. In step 604, a reference layer is formed by deposition in a Kr atmosphere of alternating Co and Pt layers, for example. In step 606, a hard layer is formed by deposition in a Kr atmosphere of alternating Co and Pt layers, for example.

As used herein, the term “anisotropy” or “anisotropic” refer to a particular axis or direction to which the magnetization of a ferromagnetic or ferrimagnetic layer tends to orientate when it does not experience an additional external field. An axial anisotropy can be created by a crystalline or interfacial effect or by a shape anisotropy, both of which allow two equivalent directions of magnetic fields. A directional anisotropy can also be created in an adjacent layer, for example, by an antiferromagnetic layer, which allows only a single magnetic field direction along a specific axis in the adjacent layer.

In view of the above, it will be understood that introduction of an anisotropy in a magnetic layer results in forcing the magnetization of the magnetic layer to be aligned along that anisotropy in the absence of an external field. In the case of a GMR or TMR element, a directional anisotropy provides an ability to obtain a coherent rotation of the magnetic field in a magnetic layer in response, for example, to an external magnetic field.

In general, magnetic materials can have a variety of magnetic characteristics and can be classified by a variety of terms, including, but not limited to, ferromagnetic, antiferromagnetic, and nonmagnetic. Description of the variety of types of magnetic materials is not made herein in detail. However, let it suffice here to say, that a ferromagnetic material is one in which magnetic moments of atoms within the ferromagnetic material tend to, on average, align to be both parallel and in the same direction, resulting in a nonzero net magnetic magnetization of the ferromagnetic material.

An antiferromagnetic material is one in which magnetic moments within the antiferromagnetic material tend to, on average, align to be parallel, but in opposite directions in sub-layers within the antiferromagnetic material, resulting in a zero net magnetization.

As used herein, the term “magnetic field sensor” is used to describe a circuit that uses a magnetic field sensing element, generally in combination with other circuits. Magnetic field sensors are used in a variety of applications, including, but not limited to, an angle sensor that senses an angle of a direction of a magnetic field, a current sensor that senses a magnetic field generated by a current carried by a current-carrying conductor, a magnetic switch that senses the proximity of a ferromagnetic object, a rotation detector that senses passing ferromagnetic articles, for example, magnetic domains of a ring magnet or a ferromagnetic target (e.g., gear teeth) where the magnetic field sensor is used in combination with a back-biased or other magnet, and a magnetic field sensor that senses a magnetic field density of a magnetic field.

As used herein, the term “magnetic field sensor” is used to describe a circuit that uses a magnetic field sensing element, generally in combination with other circuits. Magnetic field sensors are used in a variety of applications, including, but not limited to, an angle sensor that senses an angle of a direction of a magnetic field, a current sensor that senses a magnetic field generated by a current carried by a current-carrying conductor, a magnetic switch that senses the proximity of a ferromagnetic object, a rotation detector that senses passing ferromagnetic articles, for example, magnetic domains of a ring magnet or a ferromagnetic target (e.g., gear teeth) where the magnetic field sensor is used in combination with a back-biased or other magnet, and a magnetic field sensor that senses a magnetic field density of a magnetic field. As used herein, the terms “target” and “magnetic target” are used to describe an object to be sensed or detected by a magnetic field sensor or magnetic field sensing element.

Various embodiments of the concepts, systems, devices, structures and techniques sought to be protected are described herein with reference to the related drawings. Alternative embodiments can be devised without departing from the scope of the concepts, systems, devices, structures and techniques described herein. It is noted that various connections and positional relationships (e.g., over, below, adjacent, etc.) are set forth between elements in the following description and in the drawings. These connections and/or positional relationships, unless specified otherwise, can be direct or indirect, and the described concepts, systems, devices, structures and techniques are not intended to be limiting in this respect. Accordingly, a coupling of entities can refer to either a direct or an indirect coupling, and a positional relationship between entities can be a direct or indirect positional relationship.

As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s). The following definitions and abbreviations are to be used for the interpretation of the claims and the specification. As used herein, the terms “comprises,” “comprising, “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

Unless otherwise specified, the term “substantially” refers to values that are within ±10%. For example, a first direction that is “substantially” perpendicular to a second direction may refer to a first direction that is within ±10% of making a 90° angle with the second direction.

Having described exemplary embodiments of the disclosure, it will now become apparent to one of ordinary skill in the art that other embodiments incorporating their concepts may also be used. The embodiments contained herein should not be limited to disclosed embodiments but rather should be limited only by the spirit and scope of the appended claims. All publications and references cited herein are expressly incorporated herein by reference in their entirety.

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. A method, comprising:
forming a series of layers for a magnetoresistive element, including:
forming a sense layer having a free sense magnetization;
forming a tunnel barrier layer between the sense layer and a reference layer;
forming the reference layer having a fixed reference magnetization, wherein the reference layer is formed by deposition in an atmosphere with a noble gas having an atomic weight greater than Argon;
forming a hard layer having a fixed reference magnetization layer opposite to that of the reference layer due to a metallic layer in between the hard layer and the reference layer,
wherein the magnetoresistive element is configured to measure an external magnetic field oriented substantially perpendicular to the plane of the reference layer;
wherein the reference magnetizations of the reference and hard layers are oriented substantially perpendicularly to the plane of the reference and hard layers; and
wherein the sense magnetization comprises a vortex configuration in the absence of an external magnetic field, the vortex configuration being substantially parallel to the plane of the sense layer and having a vortex core magnetization along an out-of-plane axis substantially perpendicular to the plane of the sense layer.

2. The method according to claim 1, further including wherein the reference layer is formed by deposition in the atmosphere with a noble gas having an atomic weight greater than Argon.

3. The method according to claim 1, wherein the reference layer comprises alternating layers of Pt and Co.

4. The method according to claim 3, wherein Pt layers in the alternating layers of Pt and Co range from 0.2 nm to 2.0 nm in thickness.

5. The method according to claim 3, wherein Co layers in the alternating layers of Pt and Co range from 0.2 nm to 2.0 nm in thickness.

6. The method according to claim 1, wherein the reference layer comprises Pd.

7. The method according to claim 3, wherein the reference layer includes a FeCoB layer.

8. The method according to claim 7, wherein the FeCoB layer comprises Fe_{y}Co_{80-y}B₂₀ where y is between 5 and 75.

9. The method according to claim 7, wherein a thickness of the FeCoB layer ranges from 0.2 om to 2.0 nm in thickness.

10. The method according to claim 7, wherein the FeCoB layer is formed by deposition in the atmosphere.

11. The method according to claim 1, wherein the reference layer includes a Ta layer deposited in the Kr atmosphere.

12. The method according to claim 11, wherein the Ta layer has a thickness between 0.1 nm and 0.5 nm.

13. The method according to claim 1, wherein the reference layer includes a Tungsten layer deposited in the atmosphere with a noble gas having an atomic weight greater than Argon.

14. The method according to claim 13, wherein the Tungsten layer has a thickness between 0.1 nm and 0.5 nm.

15. The method according to claim 1, wherein the hard layer includes alternating layers of Pt and Co.

16. The method according to claim 15, wherein the Pt layers and the Co layers in the alternating layers have thicknesses between 0.2 nm and 2.0 nm.

17. The method according to claim 15, wherein the hard layer is deposited on a Pt buffer layer.

18. The method according to claim 17, wherein the Pt buffer layer has a thickness from 0.2 nm to 50 nm.

19. The method according to claim 15, wherein the hard layer is deposited on a Pd buffer layer.

20. The method according to claim 1, wherein the hard layer includes alternating layers of Pd and Co.

21. The method according to claim 1, further including selecting thicknesses of alternating layers of Pt and Co in the reference layer and the hard layer for perpendicular anisotropy in the atmosphere with a noble gas having an atomic weight greater than Argon.

22. The method according to claim 1, further including selecting thicknesses of alternating layers of Pt and Co in the reference and hard layers for an AF plateau value.

23. The method according to claim 1, further including selecting thicknesses of alternating layers of Pt and Co in the reference and hard layers for given magnetic compensation characteristics.

24. The method according to claim 1, wherein the metallic layer comprises Ru configured to establish RKKY AF coupling to obtain a perp SAF.

25. The method according to claim 1, further including selecting thicknesses of alternating layers of Pt and Co in the reference and hard layers for a given RKKY coupling strength.

26. The method according to claim 1, wherein the magnetoresistive element forms a part of a z-axis MR sensor having field stability up to 250 mT.

27. The method according to claim 1, wherein the noble gas having an atomic weight greater than Argon is Kr.

28. The method according to claim 1, wherein the noble gas having an atomic weight greater than Argon is Xe.

29. A magnetic field sensor formed in accordance with claim 1.

30. A method, comprising:
forming a series of layers for a magnetoresistive element, including:
forming a sense layer having a free sense magnetization;
forming a tunnel barrier layer between the sense layer and a reference layer;
forming the reference layer having a fixed reference magnetization, wherein the reference layer is formed by deposition in an atmosphere with Krypton gas;
forming a hard layer having a fixed reference magnetization layer opposite to that of the reference layer due to a metallic layer in between the hard layer and the reference layer,
wherein the magnetoresistive element is configured to measure an external magnetic field oriented substantially perpendicular to the plane of the reference layer;
wherein the reference magnetizations of the reference and hard layers are oriented substantially perpendicularly to the plane of the reference and hard layers; and
wherein the sense magnetization comprises a vortex configuration in the absence of an external magnetic field, the vortex configuration being substantially parallel to the plane of the sense layer and having a vortex core magnetization along an out-of-plane axis substantially perpendicular to the plane of the sense layer.
